(19) United States
(12) Patent Application Publication
(10) Pub. No.: US 2015/0060999 A1
(43) Pub. Date: Mar. 5, 2015

(54) POWER SEMICONDUCTOR DEVICE

(71) Applicant: Samsung Electro-Mechanics Co., Ltd., Suwon (KR)

(72) Inventors: Dong Soo SEO, Suwon (KR); Jae Hoon Park, Suwon (KR); In Hyuk Song, Suwon (KR); Ji Yeon Oh, Suwon (KR); Kee Ju Um, Suwon (KR)

(73) Assignee: Samsung Electro-Mechanics Co., Ltd., Suwon (KR)

(21) Appl. No.: 14/451,030

(22) Filed: Aug. 4, 2014

(30) Foreign Application Priority Data
Aug. 30, 2013 (KR) 10-2013-0103715

(51) Int. Cl. H01L 29/739

(52) U.S. Cl. CPC H01L 29/7396
USPC 257/330

(57) ABSTRACT

A power semiconductor device may include: a drift layer having a first conductivity; a hole accumulating layer formed on the drift layer and having the first conductivity; a well layer formed on the hole accumulating layer and having a second conductivity; an emitter region formed in an internal portion of an upper portion of the well layer and having the first conductivity; and trench gates penetrating through the emitter region, the well layer, and the hole accumulating layer, and having a gate insulating layer formed on a surface thereof. The trench gate may be sequentially divided into a first gate part, a second gate part, and a third gate part from an upper portion thereof depending on a height of a material filled in the trench gate, the first to third gate parts having different resistances from each other.

### CROSS-REFERENCE TO RELATED APPLICATION

This application claims the benefit of Korean Patent Application No. 10-2013-0103715 filed on Aug. 30, 2013, with the Korean Intellectual Property Office, the disclosure of which is incorporated herein by reference.

### BACKGROUND

The present disclosure relates to a power semiconductor device having low turn-on resistance and reduced noise generation.

An insulated gate bipolar transistor (IGBT) is a transistor manufactured to have bipolarity by forming a gate using a metal oxide semiconductor (MOS) and forming a p-type collector layer on a rear surface thereof.

Since a power metal oxide semiconductor field effect transistor (MOSFET) was developed in the related art, it has been used in fields requiring high speed switching characteristics.

However, due to structural limitations of such MOSFETs, bipolar transistors, thyristors, gate turn-off thyristors (GTO), and the like, have been used in fields requiring devices able to handle high voltages.

Since IGBTs have characteristics such as a low forward loss and a rapid switching speeds, the application of such IGBTs to fields to which existing thyristors, bipolar transistors, MOSFETs, and the like are unable to be applied, has increased.

An operation principle of such an IGBT will be described hereinafter. In the case in which an IGBT device is turned on, a voltage applied to an anode is higher than a voltage applied to a cathode, and when a voltage higher than a threshold voltage of the IGBT device is applied to a gate electrode, a polarity of a surface of a p-type well layer positioned on a lower side of the gate electrode is inversed, such that an n-type channel is formed.

An electron current injected into a drift region through the channel induces the injection of a hole current from a high-concentration p-type collector layer positioned on a lower side of the IGBT device, similar to a base current of the bipolar transistor.

Due to injection of these minority carriers at a high concentration, a conductivity modulation phenomenon in which conductivity in the drift region is increased by several tens to several hundreds of times occurs.

Unlike the MOSFET, in the IGBT, a resistance component in a drift region becomes very small due to the conductivity modulation phenomenon. Therefore, the IGBT may be used with very high voltages.

Various technologies have been developed in order to significantly increase the conductivity modulation phenomenon.

For example, there is a technology of significantly increasing the conductivity modulation phenomenon using a phenomenon in which holes are accumulated by forming a high concentration n-type semiconductor region below the p-type well layer.

As described above, the high concentration n-type semiconductor region formed below the well region is known as a hole accumulating layer.

In the case in which the hole accumulating layer is formed, an amount of accumulated holes is significantly increased, such that a high conductivity modulation phenomenon occurs. However, the holes accumulated in the hole accumulating layer have an influence on an input signal of a trench gate.

That is, the hole accumulating layer has an influence on the trench gate, such that gate noise is generated.

Such gate noise may hinder the stable supply of current.

Particularly, in the case in which a switching frequency is high, a variation width of the current is significantly increased due to the gate noise.

Therefore, a technology capable of decreasing a turn-on resistance by significantly increasing a conductivity modulation phenomenon and decreasing a gate noise has been demanded.

The following Related Art Document (Patent Document 1) relates to a power MOSFET including a low resistance gate.

In detail, the power MOSFET disclosed in Patent Document 1 is characterized by forming a conductive seed layer in a bottom part of a trench and growing a low resistance material thereon.

Since the case in which resistances of materials formed in a trench are changed according to a height of each of the layers and a hole accumulating layer are not disclosed in Patent Document 1, configurations of the present disclosure and the power MOSFET disclosed in Patent Document 1 are different from each other.

Due to the differences in the configuration as described above, a technical effect equal to that of the present disclosure may not be obtained.

### RELATED ART DOCUMENT

(Patent Document 1) Korean Patent Laid-Open Publication No. 2008-0100209

### SUMMARY

An aspect of the present disclosure may provide a power semiconductor device capable of having low turn-on resistance and reduced switching noise generation.

According to an aspect of the present disclosure, a power semiconductor device may include: a drift layer having a first conductivity; a hole accumulating layer formed on the drift layer and having the first conductivity; a well layer formed on the hole accumulating layer and having a second conductivity; an emitter region formed in an internal portion of an upper portion of the well layer and having the first conductivity; and trench gates penetrating through the emitter region, the well layer, and the hole accumulating layer, and having a gate insulating layer formed on a surface thereof, wherein the trench gate is sequentially divided into a first gate part, a second gate part, and a third gate part from an upper portion thereof depending on a height of a material filled in the trench gate, the first to third gate parts having different resistances from each other.

The first gate part may be formed in a location corresponding to a height of the well layer, the second gate part may be formed in a location corresponding to a height of the hole accumulating layer, and the third gate part may be formed in a location corresponding to a height of the drift layer.

A resistance of the second gate part may be higher than that of the third gate part.

A resistance of the second gate part may be higher than that of the first gate part.

The first to third gate parts may be electrically connected to each other.

The power semiconductor device may further include an insulating member extended from the gate insulating layer from at least one of a portion between the first and second gate parts and a portion between the second and third gate parts.

The power semiconductor device may further include a gate metal layer electrically connected to the first to third gate parts and formed on an upper surface of the drift layer.

A concentration of impurities of the hole accumulating layer may be higher than that of impurities of the drift layer.

According to another aspect of the present disclosure, a power semiconductor device may include: a drift layer having a first conductivity; a plurality of trench gates formed lengthwise in the drift layer in one direction at a predetermined interval and including a gate insulating layer formed on a surface thereof; a well layer formed between the plurality of trench gates and having a second conductivity; an emitter region formed in the well layer in one direction at a predetermined interval so as to contact the trench gate and having the first conductivity; and a hole accumulating layer formed between the drift layer and the well layer, wherein the trench gate is sequentially divided into a first gate part, a second gate part, and a third gate part from an upper portion thereof depending on a height of a material filled in the trench gate, the first to third gate parts having different resistances from each other.

The first gate part may be formed in a location corresponding to a height of the well layer, the second gate part may be formed in a location corresponding to a height of the hole accumulating layer, and the third gate part may be formed in a location corresponding to a height of the drift layer.

A resistance of the second gate part may be higher than that of the third gate part.

A resistance of the second gate part may be higher than that of the first gate part.

The first to third gate parts may be electrically connected to each other.

The power semiconductor device may include an insulating member extended from the gate insulating layer from at least one of a portion between the first and second gate parts and a portion between the second and third gate parts.

A concentration of impurities of the hole accumulating layer may be higher than that of impurities of the drift layer.

The power semiconductor device may further include a gate metal layer formed lengthwise on an upper surface of the drift layer in a direction vertical to one direction at a distal end portion of the trench gate formed lengthwise in one direction.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic perspective view of a power semiconductor device according to an exemplary embodiment of the present disclosure;

FIG. 2 is a schematic cross-sectional view illustrating flows of electrons and holes at the time of a turn-on operation of the power semiconductor device according to an exemplary embodiment of the present disclosure;

FIG. 3 is a schematic side view of the power semiconductor device according to an exemplary embodiment of the present disclosure; and

FIG. 4 is a schematic perspective view of a power semiconductor device according to another exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

In the accompanying drawings, an x-direction refers to a width direction, a y-direction refers to a length direction, and a z-direction refers to a height direction.

A power switch may be implemented by any one of a power metal oxide semiconductor field effect transistor (MOSFET), an insulated gate bipolar transistor (IGBT), a thyristor, and devices similar to the above-mentioned devices. Most of new technologies disclosed herein will be described based on the IGBT. However, several exemplary embodiments of the present disclosure disclosed herein are not limited to the IGBT, but may also be applied to other types of power switch technologies including a power MOSFET and several types of thyristors in addition to a diode. Further, several exemplary embodiments of the present disclosure will be described as including specific p-type and n-type regions. However, conductivities of several regions disclosed herein may be similarly applied to devices having conductivities opposite thereto.

In addition, an n-type or a p-type used herein may be defined as a first conductivity or a second conductivity. Meanwhile, the first and second conductivities refer to different conductivities.

Further, generally, ‘+’ refers to the state in which a region is heavily doped and ‘−’ refers to the state in which a region is lightly doped.

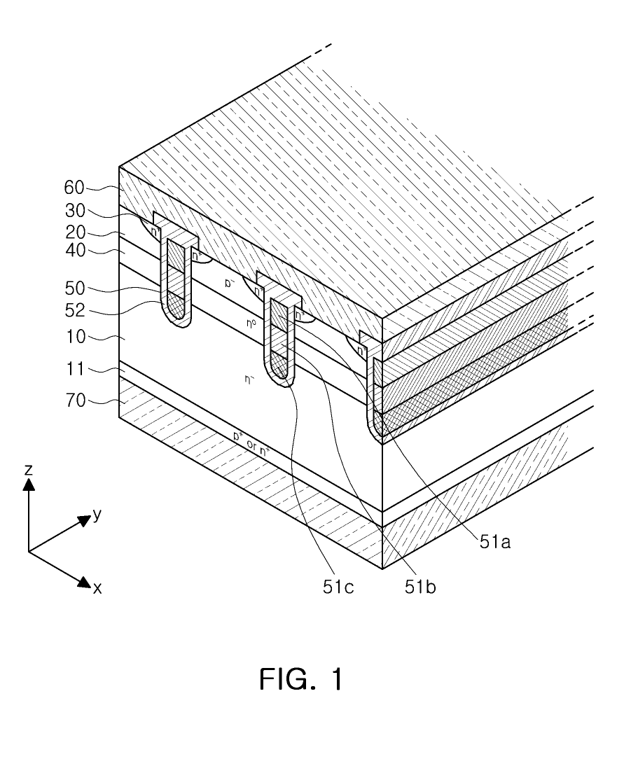

FIG. 1 is a schematic perspective view of a power semiconductor device according to an exemplary embodiment of the present disclosure.

Hereinafter, a structure of the power semiconductor device according to an exemplary embodiment of the present disclosure will be described with reference to FIG. 1.

The power semiconductor device according to an exemplary embodiment of the present disclosure may include a drift layer 10 having a first conductivity; a hole accumulating layer 40 formed on the drift layer 10 and having the first conductivity; a well layer 20 formed on the hole accumulating layer 40 and having a second conductivity; an emitter region 30 formed in an inner portion of an upper portion of the well layer 20 and having the first conductivity; and trench gates 50 penetrating through the emitter region 30, the well layer 20, and the hole accumulating layer 40, and having a gate insulating layer 52 formed on a surface thereof, wherein the trench gate 50 is sequentially divided into a first gate part 51a, a second gate part 51b, and a third gate part 51c from an upper portion thereof depending on a height of a material filled in the trench gate 50, the first to third gate parts 51a to 51c having different resistances from each other.

Alternatively, the power semiconductor device according to an exemplary embodiment of the present disclosure may have a structure including a drift layer 10 having a first conductivity; a plurality of trench gates 50 formed lengthwise in the drift layer 10 in one direction at a predetermined interval, and including a gate insulating layer 52 formed on a surface thereof; a well layer 20 formed between the plurality of trench gates 50 and having a second conductivity; an emitter region 30 formed in the well layer 20 in one direction at a predetermined interval so as to contact the trench gate 50 and having the first conductivity; and a hole accumulating layer 40 formed between the drift layer 10 and the well layer 20, wherein the trench gate 50 is sequentially divided into a first gate part 51a, a second gate part 51b, and a third gate part 51c from an upper portion thereof depending on a height of a material filled in the trench gate 50, the first to third gate parts 51a to 51c having different resistances from each other.

In detail, the first gate part 51a may be formed in a location corresponding to a height of the well layer 20, the second gate part 51b may be formed in a location corresponding to a height of the hole accumulating layer 40, and the third gate part 51c may be formed in a location corresponding to a height of the drift layer 10.

The first conductivity may be an n-type, and the second conductivity may be a p-type.

The drift layer 10 may have low-concentration n-conductivity impurities in order to maintain a blocking voltage of the power semiconductor device.

An emitter metal layer 60 may be formed on exposed upper surfaces of the well layer 20 and the collector region 30.

A buffer layer 11 may be further formed below the drift layer 10.

A conductivity of the buffer layer 11 may be an n+ type or a p+ type. In the case in which the conductivity of the buffer layer 11 is the n+ type, the power semiconductor device according to an exemplary embodiment of the present disclosure may be operated as a MOSFET, and the conductivity thereof is the p+ type, the power semiconductor device may be operated as an IGBT.

A collector metal layer 70 may be further formed below of the buffer layer 11.

In the IGBT, since the conductivity of the buffer layer 11 is the p+ type, the buffer layer 11 may inject holes in the case in which the power semiconductor device is turned on.

Due to the injection of the holes at a high concentration as described above, a conductivity modulation phenomenon that conductivity in the drift layer 10 is increased several ten to several hundred times may occur.

In order to significantly increase the conductivity modulation phenomenon, the hole accumulating layer 40 having the first conductivity may be formed on the drift layer 10.

A conductivity of the hole accumulating layer 40 may be the same as that of the drift layer 10, but a concentration of impurities of the hole accumulating layer 40 may be significantly higher than that of the drift layer 10.

In detail, the conductivity of the hole accumulating layer 40 may be an n+ type.

Since the hole accumulating layer 40 has high-concentration n-type impurities, the holes injected from the buffer layer 11 may be accumulated in the hole accumulating layer 40.

Therefore, the holes may be accumulated at a high concentration below the well layer 20, such that the conductivity modulation phenomenon may be significantly increased.

However, when the holes are excessively accumulated in the hole accumulating layer 40, a voltage applied to the trench gate 50 may be affected by charges of these holes.

That is, the voltage applied to the trench gate 50 is fluctuated by the holes accumulated in the hole accumulating layer 40, such that a noise may be generated in the case which the power semiconductor device performs a switching operation.

Therefore, according to the related art, there was a limitation in increasing a concentration of first conductivity (n-type) impurities of the hole accumulating layer 40 to a predetermined value or more.

In the power semiconductor device according to an exemplary embodiment of the present disclosure, when in the trench gate 50, the portion corresponding to the height of the well layer 20 is defined as the first gate part 51a, the portion corresponding to the height of the hole accumulating layer 40 is defined as the second gate part 51b, and the portion corresponding to the height of the drift layer 10 is defined as the third gate part 51c depending on the height of the material filled therein, resistances of the first to third gate parts 51a to 51c may be different from each other.

Required gate voltages may be different from each other depending on heights of the well layer 20, the hole accumulating layer 40, and the drift layer 10.

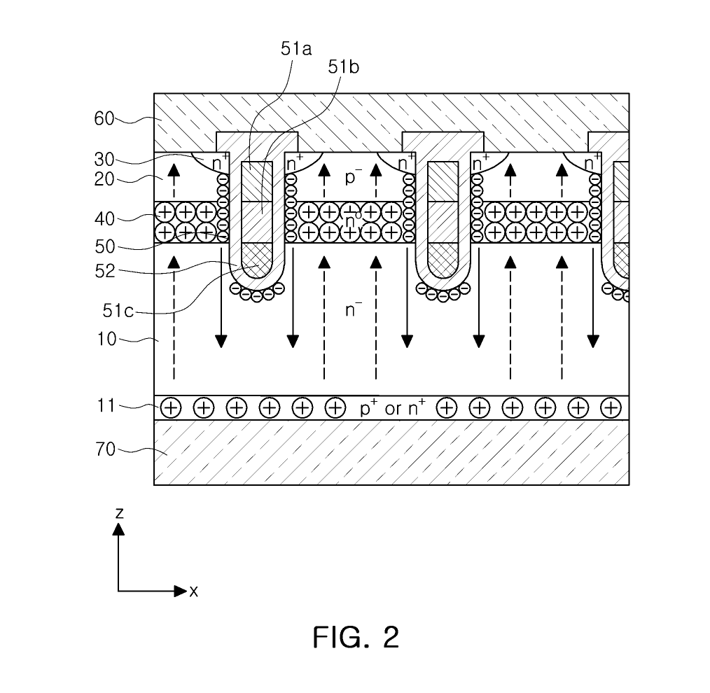

Hereinafter, gate voltages required in the respective layers will be described with reference to FIG. 2.

FIG. 2 is a schematic cross-sectional view illustrating flows of electrons and holes at the time of a turn-on operation of the power semiconductor device according to an exemplary embodiment of the present disclosure.

The well layer 20 may have a channel formed therein at the time of a turn-on operation of the power semiconductor device.

A positive voltage may be applied to the trench gate at the time of the turn-on operation of the power semiconductor device.

Therefore, as shown in FIG. 2, electrons may be pulled to a surface of the trench gate 50 by a positive electric field formed by the positive voltage, and a conductive channel may be formed in the well layer 20, such that a current may flow between an emitter and a collector.

The conductive channel may be in association with a turn-on voltage Vth, and the well layer 20 may be in close association with the blocking voltage of the power semiconductor device.

Since the well layer 20 has an influence on several characteristics of the power semiconductor device, the resistance of the first gate part 51a needs to be adjusted in consideration of this feature.

The hole accumulating layer 40 may be formed in order to significantly increase the conductivity modulation phenomenon of the power semiconductor device.

That is, since the hole accumulating layer 40 is formed by injecting n-type impurities at a high concentration, the holes may be accumulated in the hole accumulating layer 40, as shown in FIG. 2.

Since the holes have positive charges, the holes accumulated in the hole accumulating layer 40 may generate a positive electric field.

The electric field generated by the holes may have an influence on the second gate part 51b.

This will be described in detail hereinafter.

When a large number of holes having the positive charges are accumulated in the hole accumulating layer 40, a strong positive electric field may be generated by the holes accumulated in the hole accumulating layer 40.

When a positive voltage is applied to the second gate part 51b, holes having positive charges may be generated in the second gate part 51b. The holes generated in the second gate part 51b may be pushed to the vicinity by the positive electric field generated by the holes accumulated in the hole accumulating layer 40.

That is, since the holes generated in the second gate part 51b are pushed to the first gate part 51a, a concentration of the holes in the first gate part 51a may be increased as compared with the related art.

Therefore, the first gate part 51a may have a strong positive electric field due to the increased concentration of the holes and may pull more electrons to the surface of the trench gate 50 corresponding to the height thereof.

Therefore, the voltage Vth may be increased, and a wider channel may be formed, such that a large amount of current may flow.

The above-mentioned phenomenon is repeated, such that the voltage applied to the trench gate 50 is fluctuated and a current waveform is also fluctuated, thereby generating a noise.

Therefore, the amount of the holes generated in the second gate part 51b is decreased by increasing the resistance of the second gate part 51b, whereby the generation of the noise may be prevented.

In addition, since the holes are moved at a speed very slower than that of the electrons, they may not rapidly disappear in the case in which the power semiconductor device is switched to a turn-off operation.

Therefore, even in the case in which the power semiconductor device is switched to the turn-off operation, the holes accumulated in the hole accumulating layer 40 may still have an influence on the second gate part 51b.

Therefore, when the power semiconductor device is switched to the turn-off operation, the voltage applied to the second gate part 51b is fluctuated by the holes accumulated in the hole accumulating layer 40, such that a switching noise may be generated.

In order to decrease the switching noise as described above, the second gate part 51b may have a high resistance.

The second gate part 51b has a high resistance, such that an influence of the electric field generated by the holes accumulated in the hole accumulating layer 40 on the second gate part 51b may be decreased.

That is, since the resistance of the second gate part 51b is high, even in the case in which the holes accumulated in the hole accumulating layer 40 have an influence on the second gate part 51b, the voltage applied to the second gate part 51b may react insensitively to the electric field generated by the holes accumulated in the hole accumulating layer 40.

Since the voltage applied to the second gate part 51b reacts insensitively to the electric field generated by the holes accumulated in the hole accumulating layer 40, the switching noise may be significantly decreased.

The third gate part 51c formed at the portion corresponding to the height of the drift layer 10 may have a low resistance.

Since the third gate part 51c has a low resistance, a voltage drop at the time of applying the voltage may be small, such that the third gate part 51c may have a relatively high voltage.

Therefore, as shown in FIG. 2, in the case in which the power semiconductor device is turned on, electrons may be pulled in the vicinity of the third gate part 51c.

That is, more electrons may be pulled to the third gate part 51c, such that the electrons may not be scattered.

Since the electrons are not scattered, an introduction resistance of the electrons may be decreased, such that conduction loss of the power semiconductor device may be decreased.

The first to third gate parts 51a to 51c may be connected to a single gate metal layer.

Since the first to third gate parts 51a to 51c are connected to the same gate metal layer as each other, the first to third gate parts 51a to 51c may be electrically connected to each other.

That is, voltages applied to the first to third gate parts 51a to 51c may be the same as each other.

However, since the first to third gate parts 51a to 51c have resistance different from each other, even though the same voltage is applied, the first to third gate parts 51a to 51c may have different voltages from each other due to the voltage drops.

In detail, in the case in which the resistance of the second gate part 51b is higher than that of the third gate part 51c, even though the same voltage is applied to the second and third gate parts 51b and 51c by the gate metal layer, the voltage of the second gate part 51b is lower than that of the third gate part 51c.

Therefore, the second gate part 51b may become insensitive to the electric field generated by the charges accumulated in the hole accumulating layer 40, and the third gate part 51c may pull more electrons to the surface thereof.

Therefore, the power semiconductor device according to an exemplary embodiment of the present disclosure may decrease switching noise and a turn on resistance.

As another example, in the case in which the resistance of the second gate part 51b is higher than that of the first gate part 51a, even though the same voltage is applied to the first and second gate parts 51a and 51b by the gate metal layer, the voltage drop of the first gate part 51a is smaller than that of the second gate part 51b.

That is, the voltage of the first gate part 51a may be more precisely adjusted than the voltage of the second gate part 51b.

Therefore, the voltage of the first gate part 51a may be precisely adjusted, such that the power semiconductor device may be adjusted so as to have good performance, and decrease switching noise.

The trench gate 50 may be formed by etching the drift layer 10, forming the gate insulating layer 52 on a surface thereof, and filling polysilicon therein.

The polysilicon may be filled by doping materials capable of adjusting resistances, respectively, depending on the first to third gate parts 51a to 51c.

For example, the polysilicon filled in the second gate part 51b may be formed by doping a material having a high resistance, and the polysilicon filled in the third gate part 51c may be formed by doping a material having a low resistance.

As long as the first to third gate parts 51a to 51c may have different resistances, different materials may be filled in the first to third gate parts 51a to 51c from each other.

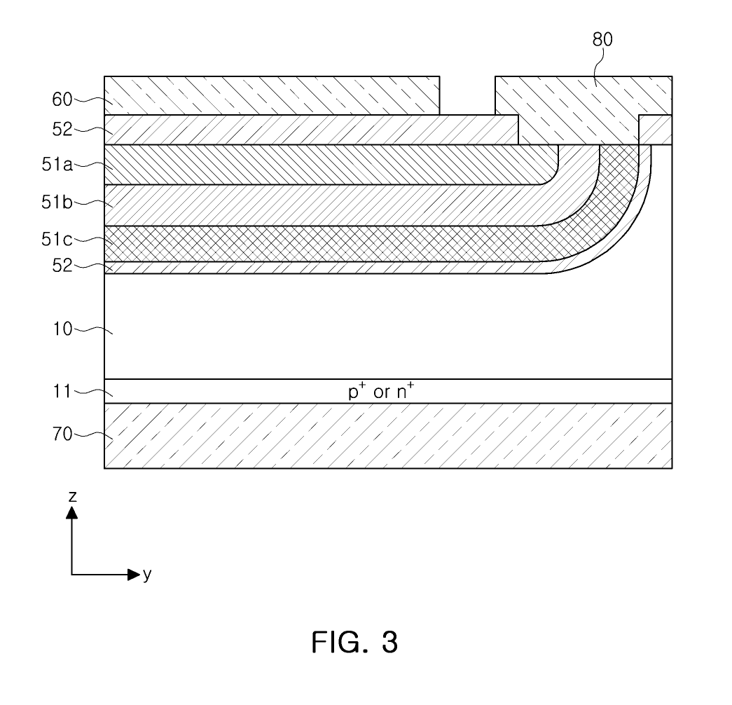

FIG. 3 is a schematic side view of the power semiconductor device according to an exemplary embodiment of the present disclosure.

The power semiconductor device according to an exemplary embodiment of the present disclosure may further include the gate metal layer 80 electrically connected to the first to third gate parts 51a to 51c and formed on an upper surface of the drift layer 10.

When the power semiconductor device is viewed from above, the gate metal layer 80 may be formed lengthwise in a direction vertical to one direction at a distal end portion of the trench gate 50 formed lengthwise in one direction.

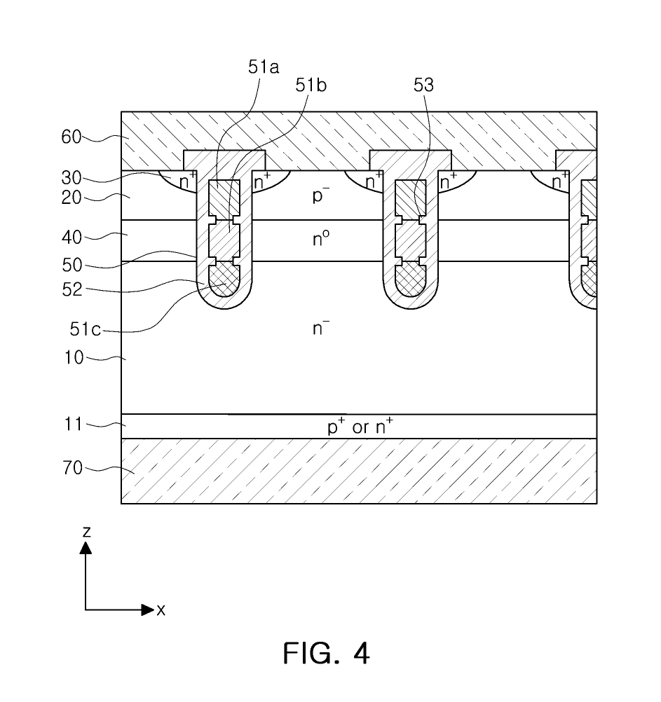

FIG. 4 is a schematic perspective view of a power semiconductor device according to another exemplary embodiment of the present disclosure.

Referring to FIG. 4, the power semiconductor device according to another exemplary embodiment of the present disclosure may further include an insulating member 53 extended from a gate insulating layer 52 from at least one of a portion between first and second gate parts 51a and 51b and a portion between second and third gate parts 51b and 51c.

The insulating member 53 does not completely insulate the first to third gate parts 51a to 51c but may decrease widths of portions at which the first to third gate parts 51a to 51c are connected to each other.

As set forth above, according to exemplary embodiments of the present disclosure, since the resistance of the material filled in the trench gate is changed depending on the layer or region contacting the trench gate, even though the same voltage is applied to the material filled in the trench gate, the electric field affecting each of the layers or regions in the trench gate may be changed.

In detail, when in the trench gate, the portion corresponding to the height of the well layer is defined as the first gate part, the portion corresponding to the height of the hole accumulating layer is defined as the second gate part, and the portion corresponding to the height of the drift layer is defined as the third gate part depending on the height of the material filled in the trench gate, the second gate part may be formed so as to have the highest resistance, thereby preventing the gate voltage from being fluctuated by the holes accumulated in the hole accumulating layer.

Fluctuation of the gate voltage may be prevented, such that generation of switching noise may be significantly decreased.

Further, the third gate part has the lowest resistance, such that when a positive voltage is applied to the trench gate, the electrons may be pulled to the surface of the gate insulating layer of the third gate part, thereby preventing the electrons from being scattered.

Since the electrons are not scattered, the introduction resistance of the electrons may be decreased, such that conduction loss of the power semiconductor device may be decreased.

While exemplary embodiments have been shown and described above, it will be apparent to those skilled in the art that modifications and variations could be made without departing from the spirit and scope of the present disclosure as defined by the appended claims.

What is claimed is:

1. A power semiconductor device comprising:
a drift layer having a first conductivity;
a hole accumulating layer disposed on the drift layer and having the first conductivity;
a well layer disposed on the hole accumulating layer and having a second conductivity;
an emitter region disposed in an internal portion of an upper portion of the well layer and having the first conductivity; and
trench gates (?) penetrating through the emitter region, the well layer, and the hole accumulating layer, a gate insulating layer being disposed on a surface of the trench gates,
wherein the trench gate is sequentially divided into a first gate part, a second gate part, and a third gate part from an upper portion thereof depending on a height of a material filled in the trench gate, the first to third gate parts having different resistances from each other.

2. The power semiconductor device of claim 1, wherein the first gate part is formed in a location corresponding to a height of the well layer, the second gate part is formed in a location corresponding to a height of the hole accumulating layer, and the third gate part is formed in a location corresponding to a height of the drift layer.

3. The power semiconductor device of claim 1, wherein a resistance of the second gate part is higher than that of the third gate part.

4. The power semiconductor device of claim 1, wherein a resistance of the second gate part is higher than that of the first gate part.

5. The power semiconductor device of claim 1, wherein the first to third gate parts are electrically connected to each other.

6. The power semiconductor device of claim 1, further comprising an insulating member extended from the gate insulating layer from at least one of a portion between the first and second gate parts and a portion between the second and third gate parts.

7. The power semiconductor device of claim 1, further comprising a gate metal layer electrically connected to the first to third gate parts and formed on an upper surface of the drift layer.

8. The power semiconductor device of claim 1, wherein a concentration of impurities of the hole accumulating layer is higher than that of impurities of the drift layer.

9. A power semiconductor device comprising:
a drift layer having a first conductivity;
a plurality of trench gates formed lengthwise in the drift layer in one direction at a predetermined interval and including a gate insulating layer formed on a surface thereof;
a well layer formed between the plurality of trench gates and having a second conductivity;
an emitter region formed in the well layer in one direction at a predetermined interval so as to contact the trench gate and having the first conductivity; and
a hole accumulating layer formed between the drift layer and the well layer,
wherein the trench gate is sequentially divided into a first gate part, a second gate part, and a third gate part from an upper portion thereof depending on a height of a material filled in the trench gate, the first to third gate parts having different resistances from each other.

10. The power semiconductor device of claim 9, wherein the first gate part is formed in a location corresponding to a height of the well layer, the second gate part is formed in a location corresponding to a height of the hole accumulating layer, and the third gate part is formed in a location corresponding to a height of the drift layer.

11. The power semiconductor device of claim 9, wherein a resistance of the second gate part is higher than that of the third gate part.

12. The power semiconductor device of claim 9, wherein a resistance of the second gate part is higher than that of the first gate part.

13. The power semiconductor device of claim 9, wherein the first to third gate parts are electrically connected to each other.

14. The power semiconductor device of claim 9, further comprising an insulating member extended from the gate insulating layer from at least one of a portion between the first and second gate parts and a portion between the second and third gate parts.

15. The power semiconductor device of claim 9, wherein a concentration of impurities of the hole accumulating layer is higher than that of impurities of the drift layer.

16. The power semiconductor device of claim 9, further comprising a gate metal layer formed lengthwise on an upper surface of the drift layer in a direction vertical to one direction at a distal end portion of the trench gate formed lengthwise in one direction.
